(19) United States
(12) Patent Application Publication
(10) Pub. No.: US 2020/0135684 A1
(43) Pub. Date: Apr. 30, 2020

(54) SEMICONDUCTOR PACKAGE

(71) Applicant: SAMSUNG ELECTRONICS CO., LTD., Suwon-si (KR)

(72) Inventors: Sun Chul KIM, Hwaseong-si (KR); Tae Hun KIM, Asan-si (KR); Ji Hwan HWANG, Hwaseong-si (KR)

(21) Appl. No.: 16/517,007

(22) Filed: Jul. 19, 2019

(30) Foreign Application Priority Data
Oct. 24, 2018 (KR) 10-2018-0127570

(51) Int. Cl. H01L 23/00; H01L 25/065; H01L 23/48; H01L 23/31

(52) U.S. Cl. CPC H01L 24/33; H01L 25/0657; H01L 2224/02372; H01L 23/3107; H01L 24/09; H01L 23/481

(57) ABSTRACT

A semiconductor package includes a first semiconductor chip including a first bonding layer, on one surface, and a chip structure stacked on the first semiconductor chip and including a second bonding layer on a surface facing the first semiconductor chip and a plurality of second semiconductor chips. The plurality of second semiconductor chips includes a chip area and a scribe area outside of the chip area, respectively, the plurality of second semiconductor chips being connected to each other by the scribe area in the chip structure. The first and second bonding layers include first and second metal pads disposed to correspond to each other and bonded to each other, respectively and first and second bonding insulating layers surrounding the first and second metal pads, respectively.

### CROSS-REFERENCE TO RELATED APPLICATION

Korean Patent Application No. 10-2018-0127570 filed on Oct. 24, 2018 in the Korean Intellectual Property Office, and entitled: “Semiconductor Package,” is incorporated by reference herein in its entirety.

### BACKGROUND

### 1. Field

Embodiments relate to a semiconductor package.

### 2. Description of the Related Art

With continuing developments in the electronics industry, there is growing demand for high-performance, high-speed, and miniaturization in electronic components. In particular, in semiconductor packages, various attempts have been made to reduce a thickness thereof.

### SUMMARY

Embodiments are directed to a semiconductor package, including a first semiconductor chip including a first bonding layer, on one surface, and a chip structure stacked on the first semiconductor chip and including a second bonding layer, on a surface facing the first semiconductor chip, and a plurality of second semiconductor chips. The plurality of second semiconductor chips may include a chip area and a scribe area outside of the chip area, respectively. The plurality of second semiconductor chips may be connected to each other by the scribe area in the chip structure. The first and second bonding layers may include first and second metal pads disposed to correspond to each other and bonded to each other, respectively and first and second bonding insulating layers surrounding the first and second metal pads, respectively.

Embodiments are also directed to a semiconductor package, including a first semiconductor chip including a first bonding layer, on one surface, and having a device area in which semiconductor devices are disposed and a via area on at least one side of the device area, the via area being provided with through vias disposed therein and a chip structure stacked on the first semiconductor chip and bonded to the first semiconductor chip through the first bonding layer and including a second bonding layer connected to the first bonding layer and a plurality of second semiconductor chips. The plurality of second semiconductor chips may include a chip area and a scribe area outside of the chip area, respectively. The plurality of second semiconductor chips may be connected to each other by the scribe area in the chip structure.

Embodiments are also directed to a semiconductor package, including a first semiconductor chip including first metal pads on a surface, a first redistribution portion on the first semiconductor chip and including a first redistribution layer electrically connected to the first semiconductor chip and second metal pads on a lower surface and bonded to the first metal pads, and a chip structure on the first redistribution portion and including a plurality of second semiconductor chips. The size of the first semiconductor chip on a plane may be substantially the same as the size of the chip structure.

### BRIEF DESCRIPTION OF THE DRAWINGS

Features will become apparent to those of skill in the art by describing in detail example embodiments with reference to the attached drawings in which:

FIG. 1 illustrates a schematic cross-sectional view of a semiconductor package according to an example embodiment;

FIGS. 2A and 2B illustrate partially enlarged views of a semiconductor package according to an example embodiment;

FIG. 3 illustrates a plan view of a partial configuration of a semiconductor package according to an example embodiment;

FIGS. 4A and 4B illustrate schematic plan views of a partial configuration of a semiconductor package according to an example embodiment;

FIG. 5 illustrates a schematic cross-sectional view of a semiconductor package according to an example embodiment;

FIG. 6 illustrates a schematic cross-sectional view of a semiconductor package according to an example embodiment;

FIG. 7 illustrates a schematic cross-sectional view of a semiconductor package according to an example embodiment;

FIGS. 8A and 8B illustrate partially enlarged views according to an example embodiment;

FIG. 9 illustrates a schematic cross-sectional view of a semiconductor package according to an example embodiment;

FIG. 10 illustrates a schematic cross-sectional view of a semiconductor package according to an example embodiment;

FIGS. 11A to 11F illustrate schematic major step-by-step views of stages in a method of manufacturing a semiconductor package according to an example embodiment; and

FIGS. 12A to 12D illustrate a schematic major step-by-step views of stages in a method of manufacturing a semiconductor package according to an example embodiment.

### DETAILED DESCRIPTION

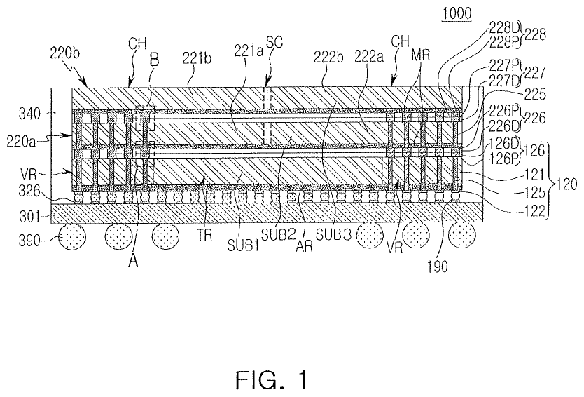

FIG. 1 is a schematic cross-sectional view of a semiconductor package according to an example embodiment.

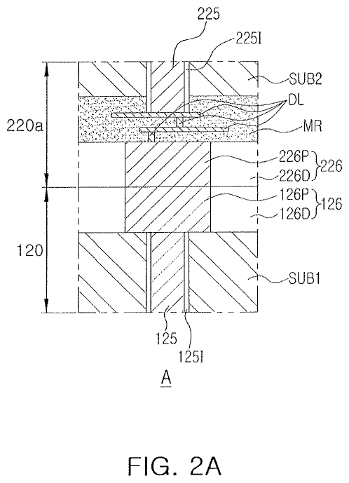

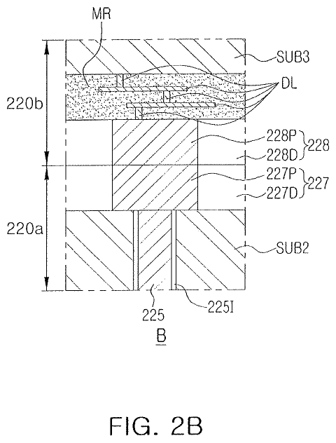

FIGS. 2A and 2B are partially enlarged views of a semiconductor package according to an example embodiment. FIGS. 2A and 2B are enlarged views of an ‘A’ area and a ‘B’ area of FIG. 1, respectively.

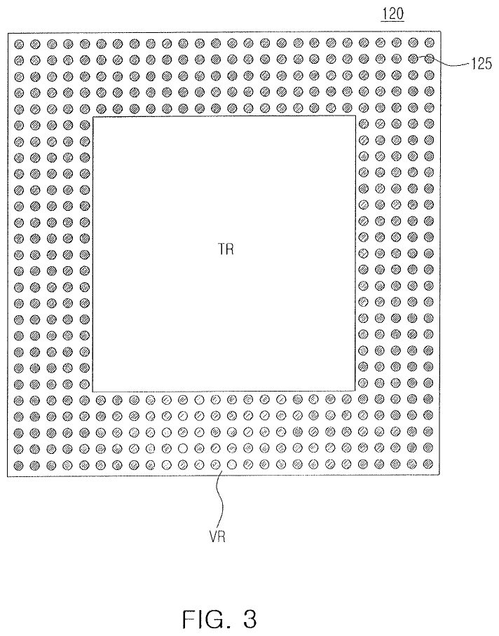

FIG. 3 is a schematic plan view of a partial configuration of a semiconductor package according to an example embodiment. In FIG. 3, a plan view of a first semiconductor chip 120 is illustrated.

Referring to FIGS. 1 to 3, a semiconductor package 1000 may include a substrate 301, a first semiconductor chip 120 mounted on the substrate 301 by bumps 190, first and second chip structures 220a and 220b stacked and disposed in an upper portion of the first semiconductor chip 120, an encapsulation portion 340 encapsulating the first semiconductor chip 120 and the first and second chip structures 220a and 220b, and connection terminals 390 on a lower surface of the substrate 301.

The first semiconductor chip 120 and the first and second chip structures 220a and 220b may be mounted on the substrate 301. The substrate 301 may include, for example, silicon (Si), glass, ceramic, or plastic. The substrate 301 may have substrate pads 326 on the upper surface thereof and the connection terminals 390 on the lower surface thereof. The substrate 301 may have a multi-layer structure including wiring patterns therein.

The first semiconductor chip 120 may include a body portion 121, connection pads 122 on a lower surface, through vias 125 penetrating at least a portion of the body portion 121, and a first bonding layer 126. The first semiconductor chip 120 may include, for example, a logic semiconductor chip and/or a memory semiconductor chip. The logic semiconductor chip may be a microprocessor, for example, a central processing unit (CPU), a controller, an application specific integrated circuit (ASIC), or the like. The memory semiconductor chip may be a volatile memory such as a dynamic random access memory (DRAM), a static random access memory (SRAM), and the like, or a non-volatile memory such as a flash memory, and the like.

The first semiconductor chip 120 may have a device area TR in which semiconductor devices are disposed and a via area VR disposed at a periphery of the device area TR, the via area VR being provided with through vias 125 disposed therein. The device area TR and the via area VR may be separate areas from each other in plan view. For example, as illustrated in FIG. 3, the via area VR may be disposed to surround the device area TR located in a center. The device area TR may be, for example, an area in which transistors constituting the logic semiconductor chip are disposed. The via area VR may be an area in which the through vias 125 are disposed to electrically connect the upper first and second chip structures 220a and 220b and the lower substrate 301. The device area TR and the via area VR are different areas formed on one substrate, such that the device area TR and the via area VR may be integrally formed and have an upper surface and a lower surface which are coplanar.

As shown in, for example, FIG. 1, the body portion 121 may include a first substrate area SUB1 and a semiconductor area AR on a lower surface of the first substrate area SUB1. The first substrate area SUB1 and the semiconductor area AR may be areas separated in a direction perpendicular to an upper surface of the first semiconductor chip 120. The first substrate area SUB1 may be disposed as a whole over the entire first semiconductor chip 120 across the device area TR and the via area VR. The first substrate area SUB1 may be an area including a semiconductor material such as silicon (Si). The semiconductor area AR may be an area in which devices such as a transistor and/or memory cells constituting the semiconductor chip are formed on a basis of the first substrate area SUB1. In particular, the devices may be formed on an area corresponding to the device area TR on a plane. The semiconductor area AR may be located at the lower portion of the first semiconductor chip 120 facing the substrate 301. Accordingly, the lower surface of the first semiconductor chip 120 may be an active surface, and the upper surface thereof may be an inactive surface. However, such a dispositional position of the active surface may be changed according to an example embodiment.

Through vias 125 may completely penetrate the first substrate area SUB1 and the semiconductor area AR of the body portion 121. The through vias 125 may provide an electrical connection between the substrate 301 and the first and second chip structures 220a and 220b. The through vias 125 may provide an electrical connection between the substrate 301 and the first and second chip structures 220a and 220b. The through vias 125 may be made of a conductive material and may include at least one of, for example, tungsten (W), aluminum (Al), and copper (Cu). As illustrated in FIG. 2A, the through via 125 may be electrically separated from the first substrate area SUB1 by a surrounding insulator such as a via insulating layer 1251.

Connection pads 122 may be disposed to be connected to the through vias 125 on the lower surface of the first semiconductor chip 120. The connection pads 122 may be made of a conductive material such as tungsten (W), aluminum (Al), copper (Cu), and the like.

The first bonding layer 126 may be on an upper surface of the first semiconductor chip 120 and may include first metal pads 126P and a first bonding insulating layer 126D disposed to surround the first metal pads 126P. The first bonding layer 126 may be a layer bonded to a second bonding layer 226 of an upper first chip structure 220a to connect the first chip structure 220a to the first semiconductor chip 120. The first metal pads 126P may be disposed to correspond to the through vias 125 on the via area VR. For example, a portion of the first metal pads 126P may be disposed in an area in which the through vias 125 are not formed and may not perform an electrical connection function but may perform a bonding function.

Bumps 190 may be on a lower surface of the first semiconductor chip 120 and may connect the connection pads 122 to the substrate pads 326 on the substrate 301. The bumps 190 may include at least one of a conductive material such as solder, tin (Sn), silver (Ag), copper (Cu), and aluminum (Al). The shape of the bumps 190 may be various shapes such as a ball, a land, a bump, a pillar, a pin, and the like. The bumps 190 may be microbumps having a smaller size than the connection terminals 390.

The first and second chip structures 220a and 220b may be sequentially stacked on the first semiconductor chip 120. The first and second chip structures 220a and 220b may have substantially the same size as the first semiconductor chip 120 on a plane. The first and second chip structures 220a and 220b may include two second lower semiconductor chips 221a and 222a and second upper semiconductor chips 221b and 222b, respectively. The second semiconductor chips 221a, 222a, 221b and 221b may include, for example, a logic semiconductor chip and/or a memory semiconductor chip. For example, the first semiconductor chip 120 may be an AP chip, and the second semiconductor chips 221a, 222a, 221b and 222b may be memory chips.

In the first and second chip structures 220a and 220b, the second lower semiconductor chips 221a and 222a and the second upper semiconductor chips 221b and 222b may be formed as a single structure without sawing two semiconductor chips. Thus, the first and second chip structures 220a and 220b may be formed of the second lower semiconductor chips 221a and 222a and the second upper semiconductor chips 221b and 222b in a non-sawed or non-singulated state. The number of the second semiconductor chips 221a, 222a, 221b and 222b included in the first and second chip structures 220a and 220b may be variously changed in example embodiments.

The second lower semiconductor chips 221a and 222a and the second upper semiconductor chips 221b and 222b may include a chip area CH and a scribe area SC, at least on one side of the chip area CH, respectively. The scribe area SC may be located between the chip areas CH in each of the second lower semiconductor chips 221a and 222a and the second upper semiconductor chips 221b and 222b, disposed side by side. According to an example embodiment, a scribe area SC may be further disposed in not only an area between the second lower semiconductor chips 221a and 222a and an area between the second upper semiconductor chips 221b and 222b disposed side by side, but also in an outer area of the second semiconductor chips 221a, 222a, 221b and 222. In each of the first and second chip structures 220a and 220b, the second lower semiconductor chips 221a and 222a and the second upper semiconductor chips 221b and 222b may be connected to each other by the scribe area SC. As described above, since the second semiconductor chips 221a, 222a, 2221b and 222b may be mounted connected to each other, the size of the entire package may be significantly reduced.

The first chip structure 220a may further include chip through vias 225 penetrating at least a portion of the second lower semiconductor chips 221a and 222a and second and third bonding layers 226 and 227. The second chip structure 220b may further include a fourth bonding layer 228.

The second lower semiconductor chips 221a and 222a and the second upper semiconductor chips 221b and 222b may include second and third substrate areas SUB2 and SUB3 and an upper semiconductor area MR on lower surfaces of the second and third substrate areas SUB2 and SUB3, respectively. The second and third substrate area SUB2 and SUB3 may be areas including a semiconductor material such as silicon (Si). The upper semiconductor areas MR may be areas in which devices such as transistors and/or memory cells constituting the semiconductor chip based on the second and third substrate areas SUB2 and SUB3. In the upper device areas MR, device layers DL constituting the devices may be disposed as illustrated in FIGS. 2A and 2B. For example, the lower surfaces of the second semiconductor chips 221a, 222a, 221b and 222b may be active surfaces, respectively.

The chip through vias 225 may be disposed in an area overlapping the via area VR of the first semiconductor chip 120. According to an example embodiment, the chip through vias 225 may be disposed to correspond to the through vias 125, or may be disposed in a smaller number. The chip through vias 225 may penetrate at least the second substrate area SUB2 of at least the second lower semiconductor chips 221a and 222a, and may penetrate at least a portion of the upper device area MR. The chip through vias 225 may provide an electrical connection between the second chip structure 220b and the first semiconductor chip 120. The chip through vias 225 may be electrically connected to the devices of the device area MR of the first chip structure 220a. The chip through vias 225 may be made of a conductive material and may include at least one of, for example, tungsten (W), aluminum (Al), and copper (Cu). As illustrated in FIGS. 2A and 2B, the chip through vias 225 may be electrically separated from the second substrate area SUB2 by an insulating upper via insulating layer 2251.

The second to fourth bonding layers 226, 227 and 228 may include second to fourth metal pads 226P, 227P and 228P and second to fourth bonding insulating layers 226D, 227D and 228D disposed to surround the second to fourth metal pads 226P, 227P and 228P.

The second bonding layer 226 may be a layer bonded to the first bonding layer 126 and connecting the first chip structure 220a to the first semiconductor chip 120. The second metal pads 226P may be electrically connected to the first metal pads 126P and may be electrically connected to the devices of the upper device area MR of the first chip structure 220a and the chip through vias 225.

The third and fourth bonding layers 227 and 228 may be layers bonded to each other and connecting the second chip structure 220b to a lower structure including the first chip structure 220a. The third bonding layer 227 may be on the inactive surface of the first chip structure 220a, that is, on the inactive surfaces of the second lower semiconductor chips 221a and 222a, and the fourth bonding layer 228 may be on the active surface of the second chip structure 220b, that is, on the active surfaces of the second upper semiconductor chips 221b and 222b. The third metal pads 227P may form the upper surface of the first chip structure 220a and may be connected to the chip through vias 225. The fourth metal pads 228P may be electrically connected to devices of the upper device area MR of the second chip structure 220b.

As illustrated in FIGS. 2A and 2B, the first and second metal pads 126P and 226P may be disposed in positions corresponding to each other and may be directly bonded, and the third and fourth metal pads 227P and 228P may be disposed in positions corresponding to each other and may be directly bonded. The first to fourth metal pads 126P, 226P, 227P and 228P may include at least one of tungsten (W), aluminum (Al), copper (Cu), tungsten nitride (WN), tantalum nitride (TaN), and titanium nitride (TiN). For example, when the first to fourth metal pads 126P, 226P, 227P and 228P are made of copper (Cu), they may be physically and electrically connected by copper (Cu)-to-copper (Cu) bonding. The first to fourth metal pads 126P, 226P, 227P and 228P connected to each other may have the same size or a similar size.

The first and second bonding insulating layers 126D and 226D and the third and fourth bonding insulating layers 227D and 228D may be bonded by dielectric-to-dielectric bonding, respectively. The first to fourth bonding insulating layers 126D, 226D, 227D and 228D may include at least one of an insulating material such as SiO, SiN, SiCN, SiOC, SiON and SiOCN.

In a semiconductor package 1000, the first semiconductor chip 120 and the first chip structure 220a and the first chip structure 220a and the second chip structure 220b may be bonded by hybrid bonding, respectively. In this case, the bonding thickness may be significantly reduced, such that the thickness of the semiconductor package 1000 may be reduced compared to a case of being connected by a bump, or the like. Thus, the semiconductor package 1000 may have a reduced thickness while having a structure in which the first and second chip structures 220a and 220b including memory chips are stacked on the first semiconductor chip 120, for example, an AP chip. Therefore, there may be a margin capable of increasing the thicknesses of the semiconductor chip 120 and the first and second chip structures 220a and 220b relatively in the semiconductor package 1000, which is advantageous from a viewpoint of heat dissipation. In addition, the semiconductor package 1000 may have a reduced thickness and may not include a redistribution layer, such that the process may be simplified.

An encapsulation portion 340 may be disposed to surround the upper surface of the substrate 301, the bumps 190, the first semiconductor chip 120, and the first and second chip structures 220a and 220b to protect the first semiconductor chip 120 and the first and second chip structures 220a and 220b. The encapsulation portion 340 may be formed of, for example, a silicone-based material, a thermosetting material, a thermoplastic material, a UV-treatment material, or the like. The encapsulation portion 340 may be formed of a polymer such as resin, and may be formed of, for example, an epoxy molding compound (EMC). According to an example embodiment, the encapsulation portion 340 may be omitted.

Connection terminals 390 may be disposed in a lower portion of the substrate 301. The connection terminals 390 may connect the semiconductor package 1000 to a mainboard, or the like of an electronic device on which the semiconductor package 1000 is mounted. The connection terminals 390 may include at least one of a conductive material such as solder, tin (Sn), silver (Ag), copper (Cu), and aluminum (Al). The shape of the connection terminals 390 may be various shapes such as a land, a bump, a pillar, a pin, and the like, in addition to a ball shape.

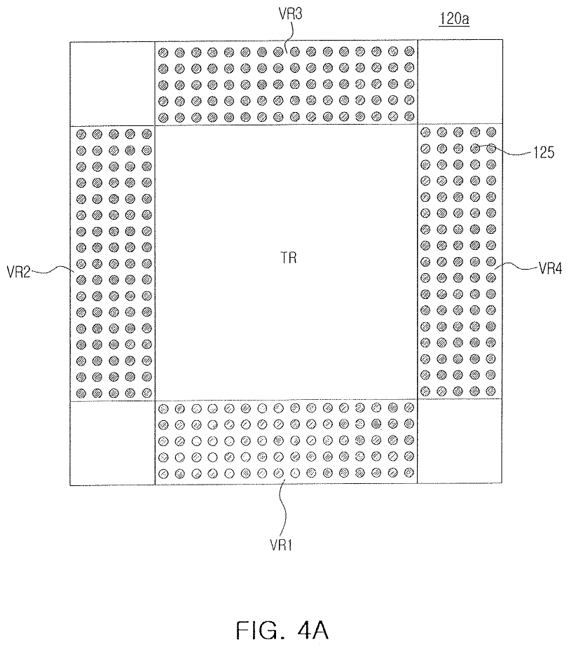

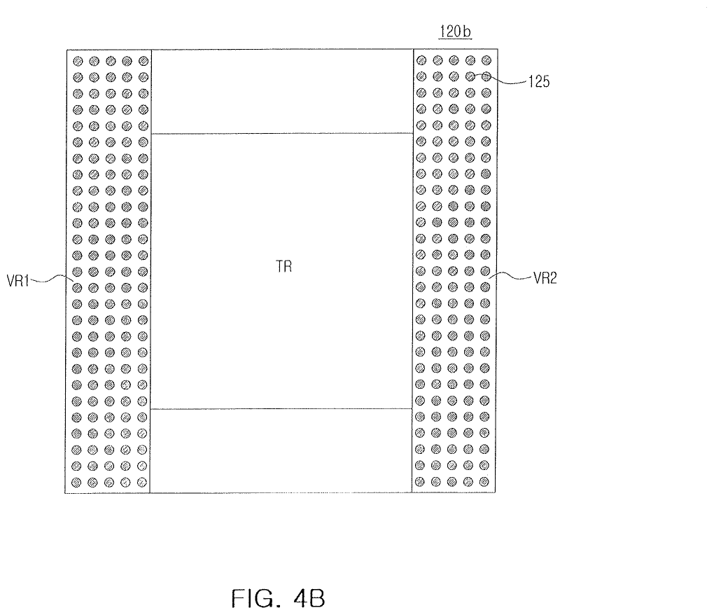

FIGS. 4A and 4B are schematic plan views of a partial configuration of a semiconductor package according to an example embodiment. In FIGS. 4A and 4B, areas corresponding to FIG. 3 are illustrated.

Referring to FIG. 4A, a first semiconductor chip 120a may include a device area TR in which semiconductor devices are disposed and first to fourth via areas VR1, VR2, VR3 and VR4 disposed separately from each other along a periphery of the device area TR, the first to fourth via areas VR1, VR2, VR3 and VR4 being provided with the through vias 125 disposed therein. The first to fourth via areas VR1, VR2, VR3, and VR4 may be disposed to be in contact with respective surfaces of the device area TR on a plane.

Referring to FIG. 4B, a first semiconductor chip 120b may have a device area TR in which semiconductor devices are disposed and first and second via areas VR1 and VR2 disposed separately from each other along a periphery of the device area TR, the via areas VR1 and VR2 being provided with the through vias 125 are disposed. The first and second through via areas VR1 and VR2 may be disposed to be in contact with the respective facing surfaces of the device area TR on the plane and may be extended and disposed by a width in one direction of the first semiconductor chip 120b.

As described above, In an example embodiment, in the case of the via areas VR1 and VR2, the via area may be provided as an area disposed separately in plural, and the via areas VR1 and VR2 may be disposed in various forms at a periphery of the device area TR.

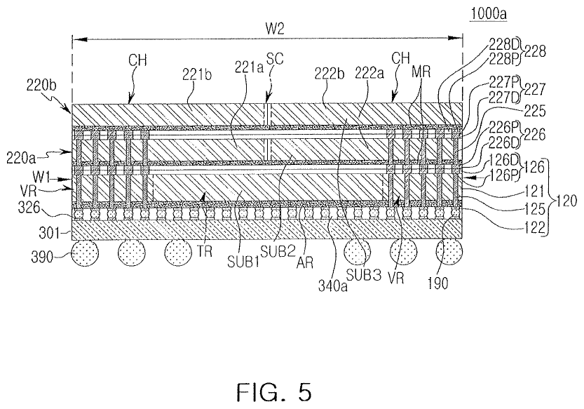

FIG. 5 is a schematic cross-sectional view of a semiconductor package according to an example embodiment.

Referring to FIG. 5, in a semiconductor package 1000a, the substrate 301 may have substantially the same size as the first semiconductor chip 120 and the first and second chip structures 220a and 220b, and side surfaces of the first semiconductor chip 120 and the first and second chip structures 220a and 220b may be exposed externally. In one direction, a width W1 of the first semiconductor chip 120 may be substantially the same as a width W2 of the first and second chip structures 220a and 220b. Thus, the first semiconductor chip 120 may have substantially the same size as the first and second chip structures 220a and 220b on the plane, which may be substantially the same as the size of the semiconductor package 1000a. An encapsulation portion 340a may be located to fill between the substrate 301 and the bumps 190.

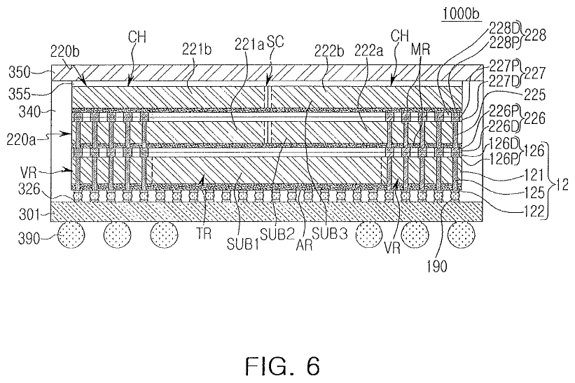

FIG. 6 is a schematic cross-sectional view of a semiconductor package according to an example embodiment.

Referring to FIG. 6, a semiconductor package 1000b may further include a heat dissipation layer 350 and an adhesive layer 355.

The heat dissipation layer 350 may be on the upper surface of the second chip structure 220b. The heat dissipation layer 350 may be stacked on the second chip structure 220b via the adhesive layer 355. The heat dissipation layer 350 may be made of a material having higher thermal conductivity than the first and second chip structures 220a and 220b, such that heat generated from the first and second chip structures 220a and 220b may be dissipated upwardly. The heat dissipation layer 350 may be a metal layer made of a metal, for example, such as copper (Cu).

The heat dissipation layer 350 may have a larger size than the first and second chip structures 220a and 220b. In an example embodiment, the heat dissipation layer 350 may have substantially the same size as the semiconductor package 1000b on a plane. According to an example embodiment, the heat dissipation layer 350 may have the same size as the first and second chip structures 220a and 220b.

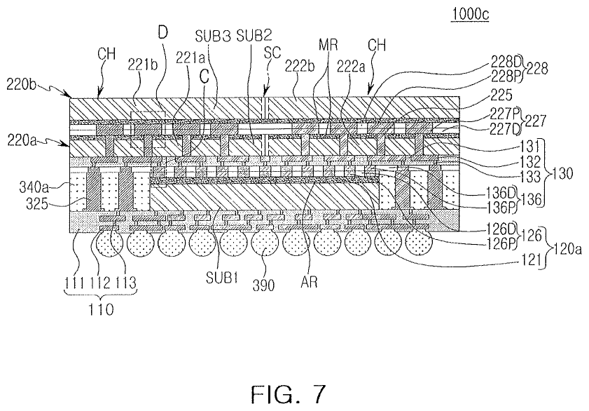

FIG. 7 is a schematic cross-sectional view of a semiconductor package according to an example embodiment.

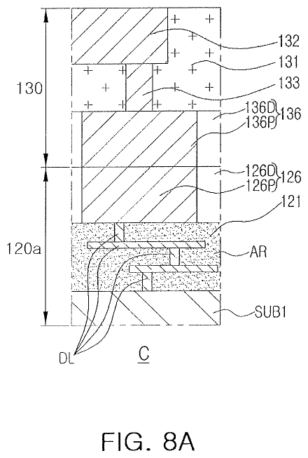

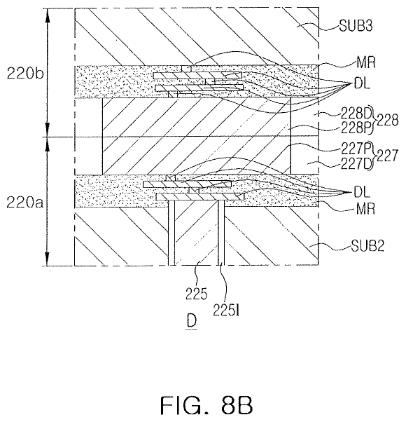

FIGS. 8A and 8B are partially enlarged views of a semiconductor package according to an example embodiment. FIGS. 8A and 8B are enlarged views of a ‘C’ area and a ‘D’ area of FIG. 7, respectively.

Referring to FIGS. 7, 8A, and 8B, a semiconductor package 1000c may include a first semiconductor chip 120a, a first redistribution portion 110 disposed in a lower portion of the first semiconductor chip 120a, a second redistribution portion 130 disposed in an upper portion of the first semiconductor chip 120a, an encapsulation portion 340a encapsulating the first semiconductor chip 120a, conductive posts 325 penetrating the encapsulation portion 340a, first and second chip structures 220a and 220b stacked and on the second redistribution portion 130, and connection terminals 390 disposed in a lower portion of the first redistribution portion 110. The semiconductor package 1000c may be a fan-out type semiconductor package in which the first semiconductor chip 120a is extended to an external area of the first semiconductor chip 120a and redistributed. Therefore, the first redistribution portion 110 may include an area which is not overlapped with the first semiconductor chip 120a on a plane. In FIGS. 7 to 8B, the same reference numerals as those in FIG. 1 illustrate the same or corresponding configuration, the above-description with reference to FIG. 1 may be equally applied.

Relative to the example embodiment of FIG. 1, the first semiconductor chip 120a may not include the via area VR, may only include an area corresponding to the device area TR of FIG. 1. The body portion 121 of the first semiconductor chip 120a may include a first substrate area SUB1 and a device area AR, and the device area AR may be located in an upper portion thereof.

In the present example embodiment, the first semiconductor chip 120a may have a smaller size than the first and second chip structures 220a and 220b. Accordingly, the encapsulation portion 340a may be disposed outside of the first semiconductor chip 120a between the first and second redistribution portions 110 and 130 to encapsulate the first semiconductor chip 120a. Conductive posts 325 penetrating the encapsulation portion 340a and connecting the first redistribution portion 110 and the second redistribution portion 130 may be further disposed. The conductive posts 325 may have an area having a relatively large width at a lower end.

The first redistribution portion 110 may be disposed in a lower portion of the first semiconductor chip 120a to redistribute the first semiconductor chip 120a. The first redistribution portion 110 may include a first wiring insulating layer 111, first redistribution layers 112 and first vias 113. The number of layers and disposition of the first wiring insulating layer 111, the first redistribution layers 112 and the first vias 113 constituting the first redistribution portion 110 may be various changed in the example embodiments.

The first wiring insulating layer 111 may be made of an insulating material, for example, a photoimageable dielectric (PID) resin. In this case, the first wiring insulating layer 111 may further include an inorganic filler. The first wiring insulating layer 111 may be made of a plurality of layers depending on the number of layers of the first redistribution layers 112, and may be made of the same material as each other, or different materials from each other. The first redistribution layers 112 and the first vias 114 may serve to redistribute the wiring of the first semiconductor chip 120a. The first vias 113 may be completely filled with a conductive material. The conductive material may have a shape formed along the wall of a via hole, and may have various shapes such as a cylindrical shape as well as a taper shape. The first redistribution layers 112 and the first vias 113 may be formed of a conductive material such as copper (Cu), aluminum (Al), silver (Ag), tin (Sn), gold (Au), nickel (Ni), lead (Pb), titanium (Ti), or alloys thereof.

The second redistribution portion 130 may be disposed in an upper portion of the first semiconductor chip 120a and may be electrically connected to the first semiconductor chip 120a and the first redistribution portion 110. The second redistribution portion 130 may include a second wiring insulating layer 131, second redistribution layers 132, second vias 133, and a second bonding layer forming a lower surface. The number of layers and disposition of the second wiring insulating layer 131, the second redistribution layers 132, and the second vias 133 constituting the second redistribution portion 130 may be variously changed in the example embodiments.

The second wiring insulating layer 131 may be made of an insulating material such as the first wiring insulating layer 111, for example, a photoimageable dielectric (PID) resin. The second redistribution layers 132 and the second vias 133 may include a conductive material, such as copper (Cu), aluminum (Al), silver (Ag), tin (Sn), nickel (Ni), lead (Pb), titanium (Ti), or alloys thereof.

The second bonding layer 136 may include second metal pads 136P and a second bonding insulating layer 136D disposed to surround the second metal pads 136P. The second metal pads 136P may be connected by the second redistribution layers 132 and the second vias 133 provided thereabove. The second bonding layer 136 may be a layer bonded to the first bonding layer 126 of the first semiconductor chip 120a provided therebelow and connecting the first and second chip structures 220a and 220b to the first semiconductor chip 120a and the first redistribution portion 110 provided therebelow.

The first and second chip structures 220a and 220b may be sequentially stacked on the second redistribution portion 130 at an upper portion of the first semiconductor chip 120a. The first chip structure 220a may include the second lower semiconductor chips 221a and 222a, and may further include the chip through vias 225 penetrating at least portions of the second lower semiconductor chips 221a and 222a and a third bonding layer 227. The second chip structure 220b may include the second upper semiconductor chips 221b and 222b, and may further include a fourth bonding layer 228. As illustrated in FIG. 8B, the upper surfaces of the second lower semiconductor chips 221a and 222a may be the active surface, and the lower surfaces of the second upper semiconductor chips 221b and 222b may be the active surface. Therefore, the first and second chip structures 220a and 220b may be stacked such that the active surfaces face each other in a face-to face fashion.

As illustrated in FIGS. 8A and 8B, the first and second metal pads 126P and 136P may be disposed in positions corresponding to each other and may be directly bonded, and the third and fourth metal pads 227P and 228P may be disposed in positions corresponding to each other and may be directly bonded. The first to fourth metal pads 126P, 136P, 227P and 228P may be physically and electrically connected by copper (Cu)-to-copper (Cu) bonding, for example, when they are made of copper (Cu). The first to fourth metal pads 126P, 136P, 227P and 228P, connected to each other, may have the same size or the similar size. The first and second bonding insulating layers 126D and 136D and the third and fourth bonding insulating layers 227D and 228D may be bonded by dielectric-to-dielectric bonding, respectively.

In the semiconductor package 1000c, the first semiconductor chip 120a and the second redistribution portion 130 and the first chip structure 220a and the second chip structure 220b may be bonded by hybrid bonding, respectively. In this case, the bonding thickness may be significantly reduced, such that the thickness of the semiconductor package 1000c may be reduced compared with the case of being connected by a bump, or the like.

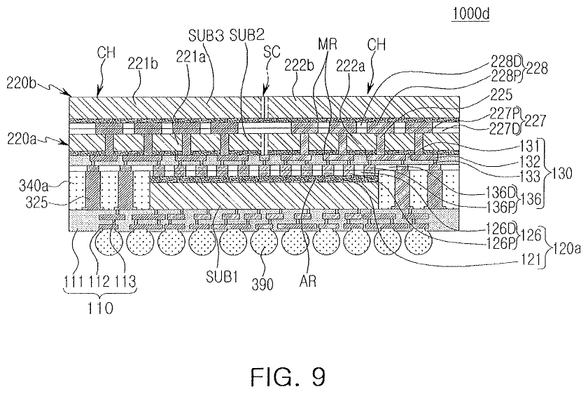

FIG. 9 is a schematic cross-sectional view of a semiconductor package according to an example embodiment.

Referring to FIG. 9, in a semiconductor package 1000d, the lower surfaces of the second semiconductor chips 221a, 222a, 221b and 222b may all be active surfaces. Therefore, the first and second chip structures 220a and 220b may be stacked in a face-to-back fashion such that the active surfaces are all facing downward. As such, In an example embodiment, a stacking direction of the first and second chip structures 220a and 220b may be variously determined according to a manufacturing process, and the like. Similarly, in the case of the first semiconductor chip 120a, the direction of the active surfaces may be variously changed according to an example embodiment.

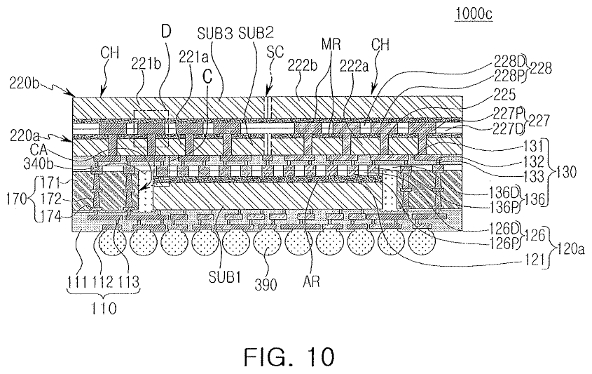

FIG. 10 is a schematic cross-sectional view of a semiconductor package according to an example embodiment.

Referring to FIG. 10, a semiconductor package 1000e may further include a core layer 170 surrounding the first semiconductor chip 120a.

The core layer 170 may include a through hole CA penetrating upper and lower surfaces such that the first semiconductor chip 120a is mounted. The through hole CA may be formed in a center of the core layer 170. In addition, in some example embodiments, the through hole CA may not completely penetrate the lower surface, but may have a cavity shape. The core layer 170 may be hybrid-bonded to the first redistribution portion 110, similarly to the first semiconductor chip 120a.

The core layer 170 may include a core insulating layer 171, core wiring layers 172, and core vias 174. The core wiring layers 172 and the core vias 174 may be disposed to electrically connect the upper and lower surfaces of the core layer 170. The core wiring layers 172 may be connected to the first and second redistribution layers 112 and 132 of the first and second redistribution portions 110 and 130. The core wiring layers 172 may be disposed inside the core insulating layer 171. The core wiring layers 172 exposed through a lower surface of the core layer 170 of the core wiring layers 172 may be embedded in the core insulating layer 171 and disposed, and it may be a structure according to the manufacturing process. According to an example embodiment, the core layer 170 may not include the core wiring layers 172 and the core vias 174 but may only include the core insulating layer 171. In the present example embodiment, the core vias 174 are illustrated to have a tapered shape increasing in a width toward the lower portion, for example, and the shape and the tapered direction, and the like, of the core vias 174 may be changed according to the process sequence.

The core insulating layer 171 may include an insulating material, for example, a thermosetting resin such as an epoxy resin or a thermoplastic resin such as polyimide, and may further include an inorganic filler. In another implementation, the core insulating layer 171 may be formed of a resin impregnated with a core material such as glass fiber, glass cloth or glass fabric together with an inorganic filler, for example, prepreg, Ajinomoto Build-up Film (ABF), FR-4, or bismaleimide triazine (BT). The core wiring layers 172 and the core vias 174 may include a metal material such as copper (Cu), or the like.

An encapsulation portion 340b may fill the space in the through hole CA of the core layer 170 to encapsulate the through hole CA and may extend on the lower surface of the core layer 170. Depending on the manufacturing process, the encapsulation portion 340b may extend on the upper surface of the core layer 170. The encapsulation portion 340b may fill at least a portion of the space between the first semiconductor chip 120 and the inner side wall of the through hole CA. Thus, the encapsulation portion 340b may also serve as an adhesive layer.

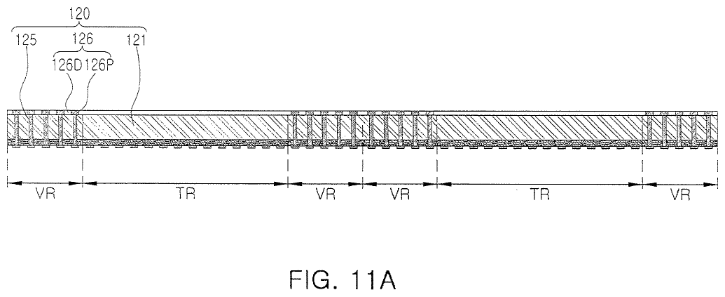

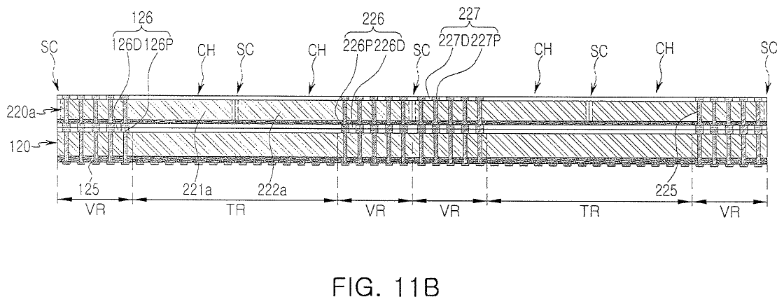

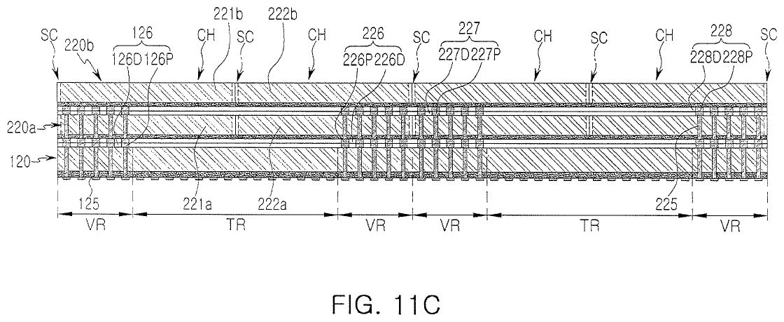

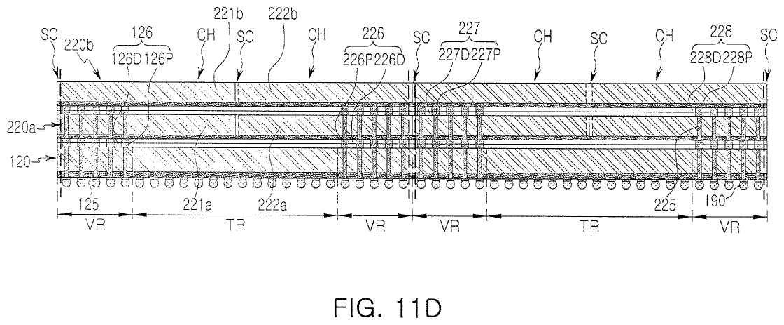

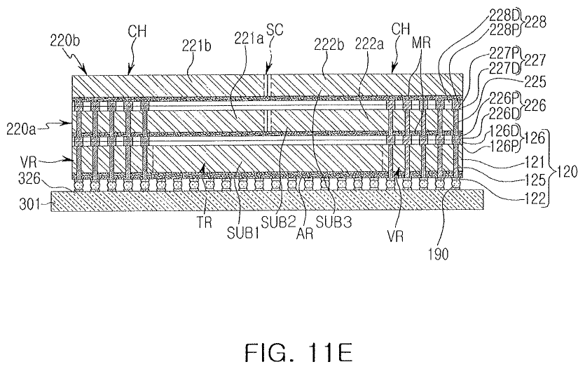

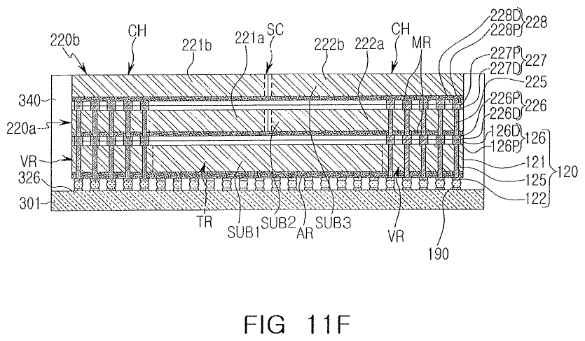

FIGS. 11A to 11F schematically illustrate major step-by-step views of stages in a method of manufacturing a semiconductor package according to an example embodiment. FIGS. 11A to 11F illustrate an example manufacturing method of the semiconductor package of FIG. 1.

Referring to FIG. 11A, the first semiconductor chips 120 may be formed at a wafer level.

The first semiconductor chip 120 may be provided by forming a device area TR including semiconductor devices on one semiconductor substrate and forming through vias 125 at a periphery of the device area TR to form a via area VR. The device area TR and the via area VR may have different interfaces or may not be clearly distinguished.

The through vias 125 may be formed, for example, in a via-last structure, a via-middle, or a via-first structure. For reference, a via-first structure may refer to a structure in which a through via is formed first before the device area AR is formed in the body portion 121, a via-middle structure may refer to a structure in which a circuit such as a transistor, or the like, of the device area AR is formed and then a through via is formed before wirings are formed at an upper portion thereof, and a via-last structure may refer to a structure in which a through via is formed after all of the wirings are formed.

The first semiconductor chip 120 may be prepared by forming connection pads 122 on the active surface, forming a first bonding layer 126 including first metal pads 126P and a first bonding insulating layer 126D on the inactive surface.

Referring to FIG. 11B, the first chip structure 220a may be bonded on the first semiconductor chips 120.

The first chip structure 220a have the second lower semiconductor chips 221a and 222a formed on one substrate and may be prepared without chips 221a and 222a being sawn apart. Therefore, the second lower semiconductor chips 221a and 222a may include a chip area CH and a scribe area SC in at least one side of the chip area CH, respectively, and the scribe areas SC of each of the second lower semiconductor chips 221a and 222a may be connected to each other. The first chip structure 220a may be manufactured by forming the upper through vias 225 in an area corresponding to the via area VR or overlapping the via area VR of the first semiconductor chips 120 and forming the second and third bonding layers 226 and 227 on the lower surface and the upper surface, respectively.

The first chip structure 220a may be connected by hybrid bonding the first bonding layer 126 of the first semiconductor chip 120 and the second bonding layer 226 of the first chip structure 220a. The first semiconductor chip 120 and the first chip structure 220a may be directly bonded without interposing an adhesive such as a separate adhesive layer. For example, the first semiconductor chip 120 and the first chip structure 220a may form coupling at an atomic level by a pressurization process. According to an example embodiment, a surface treatment process such as a hydrogen plasma treatment may be further performed on bonding surfaces of the first semiconductor chip 120 and the first chip structure 220a to enhance a bonding force before bonding. The first semiconductor chip 120 and the first chip structure 220a may be bonded to a wafer to wafer at a wafer level.

Referring to FIG. 11C, the second chip structure 220b may be bonded on the first chip structure 220a.

The second chip structure 220b, similar to the first chip structure 220a, may form the second upper semiconductor chips 221b and 222b on one substrate and may be prepared without being sawed. The second chip structure 220b may be provided by forming a fourth bonding layer 228 on the lower surface.

The second chip structure 220b may be bonded on a stacked structure of the first semiconductor chip 120 and the first chip structure 220a by hybrid bonding the third bonding layer 227 and the fourth bonding layer 228. The first chip structure 220a and the second chip structure 220b may be directly bonded without interposing an adhesive such as a separate adhesive layer. The first chip structure 220a and the second chip structure 220b may be bonded to wafer to wafer at the wafer level.

Referring to FIG. 11D, bumps 190 may be formed on the lower surface of the first semiconductor chip 120, and a stacked structure of the first semiconductor chip 120 and the first and second chip structures 220a and 220b may be sawed in a package unit.

The bumps 190 may be formed using a deposition or plating process and a reflow process.

The stacked structure may be sawed in a package unit and may be cut such that one package includes one first semiconductor chip 120 and four second semiconductor chips 221a, 222a, 221b and 222b. A singulation process may be performed in the package unit along a portion of the scribe areas SC of the first and second chip structures 220a and 220b. Thus, in one package, the scribe area SC may be removed or partially left outside of the chip areas CH, and the scribe areas SC may remain as it is between the chip areas CH.

Referring to FIG. 11E, the stacked structure cut in package units may be mounted on the substrate 301.

By connecting the bumps 190 to substrate pads 326 on the substrate 301, the stacked structure may be mounted.

Referring to FIG. 11F, an encapsulation portion 340 encapsulating the stacked structure may be formed.

The encapsulation portion 340 may be formed by forming a material constituting the encapsulation portion 340 on the stacked structure by a method such as lamination, coating, or the like, and then curing the material. The coating method may be, for example, a screen printing method or a spray printing method.

Next, by forming the connection terminals 390 on the lower surface of the substrate 301, the semiconductor package 1000 of FIG. 1 may be manufactured.

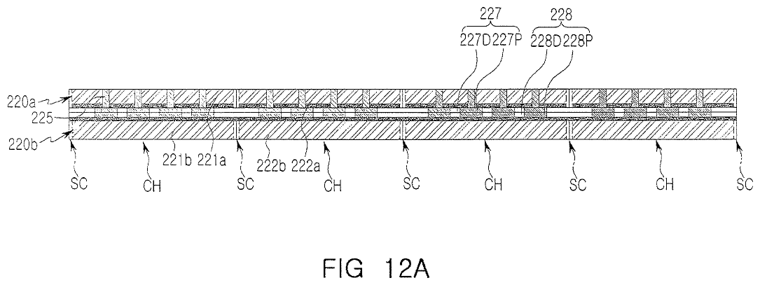

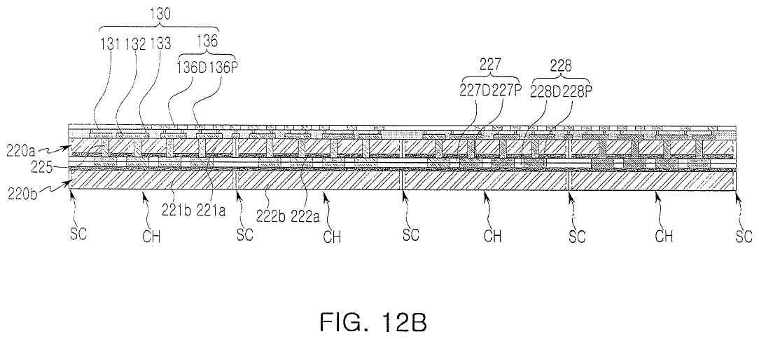

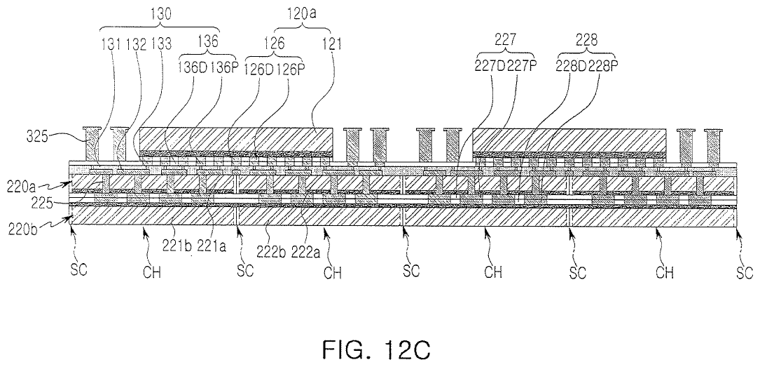

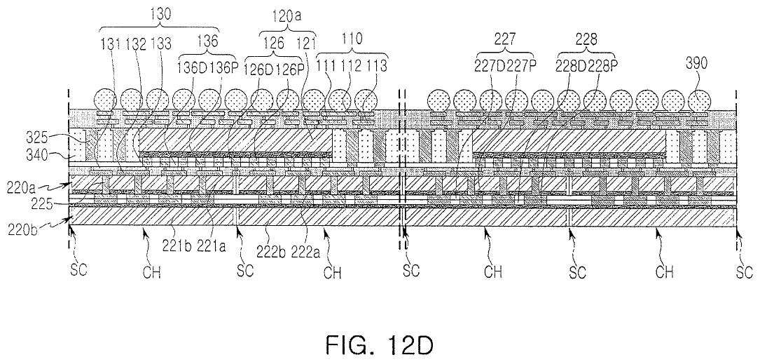

FIGS. 12A to 12D are major step-by-step views schematically illustrating a method of manufacturing a semiconductor package according to an example embodiment. In FIGS. 12A to 12D, an example manufacturing method of the semiconductor package of FIG. 7 is illustrated. Hereinafter, a description overlapping the description with reference to FIGS. 11A to 11F will not be repeated.

Referring to FIG. 12A, the first chip structure 220a may be bonded on the second chip structure 220b.

The first and second chip structures 220a and 220b may be manufactured and prepared as described above with reference to FIGS. 11B and 11C. The first and second chip structures 220a and 220b may be bonded to each other by hybrid bonding the third bonding layer 227 and the fourth bonding layer 228. The first chip structure 220a and the second chip structure 220b may be directly bonded without interposing an adhesive such as a separate adhesive layer. The first chip structure 220a and the second chip structure 220b may be bonded to the wafer to wafer at the wafer level.

Referring to FIG. 12B, a second redistribution portion 130 may be formed on the first and second chip structures 220a and 220b.

The second redistribution portion 130 may be partially manufactured by repeatedly performing a process of forming the second wiring insulating layer 131 to a certain thickness, a process of forming a via hole penetrating a portion of the second wiring insulating layer 131, and a process of filling the via hole using a plating process, or the like to form the second vias 133 and the second redistribution layers 132 on the second vias 133.

Next, a second bonding layer 136 may be formed by forming a patterned second bonding insulating layer 136D at the uppermost portion of the second redistribution portion 130, and forming second metal pads 136P in the patterned area using a plating process, or the like.

Referring to FIG. 12C, conductive posts 325 may be formed on the second redistribution portion 130 and the first semiconductor chips 120a may be bonded.

The conductive posts 325 may be formed by forming mask patterns and performing a plating or deposition process.

The first semiconductor chip 120a may be bonded to each other by hybrid bonding the second bonding layer 136 of the second redistribution portion 130 and the first bonding layer 126 of the first semiconductor chip 120a. The first semiconductor chip 120a and the second redistribution portion 130 may be directly bonded without interposing an adhesive such as a separate adhesive layer.

Referring to FIG. 12D the encapsulation portion 340a encapsulating the conductive posts 325 and the first semiconductor chips 120a may be formed, a first redistribution portion 110 may be formed. Then, the connection terminals 390 may be formed.

The first redistribution portion 110 may be manufactured by repeatedly performing a process of forming a first wiring insulating layer 111 to a certain thickness, a process of forming a via hole penetrating a portion of the first wiring insulating layer 111, and a process of filling the via hole using a plating process, or the like, to form the first vias 113 and the first redistribution layers 112 on the first vias 113.

After forming the connection terminals 390 on the first redistribution portion 110, by cutting the connection terminals 390 through a sawing process in units of unit packages, the semiconductor package 1000c of FIG. 7 may be manufactured. The cutting process may be performed in the units of unit packages along a portion of the scribe area SC of the first and second chip structures 220a and 220b. Thus, in one package, the scribe area SC may be removed or partially left outside of the chip areas CH, and the scribe areas SC may remain between the chip areas CH.

By way of summation and review, in terms of function, a system-in-package (SIP), requiring complexation and multifunctionalization has been considered, and in terms of structures, a package in which a plurality of semiconductor chips are stacked and mounted on one package substrate, or a package-on-package (PoP) structure in which a package is stacked on a package, have been considered.

As set forth above, by connecting a memory structure and a semiconductor chip by hybrid bonding, a semiconductor package having a reduced thickness and high reliability may be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor package, comprising:
a first semiconductor chip including a first bonding layer on a surface; and
a chip structure stacked on the first semiconductor chip and including a second bonding layer on a surface facing the first semiconductor chip and a plurality of second semiconductor chips, wherein:
the plurality of second semiconductor chips include a chip area and a scribe area outside of the chip area, respectively, the plurality of second semiconductor chips being connected to each other by the scribe area in the chip structure, and
the first and second bonding layers include first and second metal pads disposed to correspond to each other and bonded to each other, respectively, and first and second bonding insulating layers surrounding the first and second metal pads, respectively.

2. The semiconductor package as claimed in claim 1, wherein the plurality of second semiconductor chips form the chip structure without being sawed from each other.

3. The semiconductor package as claimed in claim 1, wherein the chip structure has substantially the same size as the first semiconductor chip on a plane.

4. The semiconductor package as claimed in claim 1, wherein side surfaces of the chip structure are exposed externally.

5. The semiconductor package as claimed in claim 1, wherein the first semiconductor chip includes a device area in which semiconductor devices are disposed and a via area on at least one side of the device area, the via area being provided with first through vias disposed therein electrically connecting the chip structure and the first semiconductor chip.

6. The semiconductor package as claimed in claim 5, wherein the first semiconductor chip further includes a substrate on an entirety of the device area and the via area.

7. The semiconductor package as claimed in claim 5, wherein the via area is disposed to surround the device area on a plane.

8. The semiconductor package as claimed in claim 5, wherein the via area includes a plurality of areas disposed to be spaced apart from each other along a perimeter of the device area on a plane.

9. The semiconductor package as claimed in claim 5, wherein the chip structure further includes second through vias disposed in an area overlapping the via area.

10. The semiconductor package as claimed in claim 1, wherein:
the chip structure includes first and second chip structures stacked vertically,
the first chip structure is disposed in a lower portion and includes the second bonding layer and a third bonding layer, and the second chip structure is disposed in an upper portion and includes a fourth bonding layer connected to the third bonding layer, and
the third and fourth bonding layers includes third and fourth metal pads disposed to correspond to each other and bonded to each other, respectively, and third and fourth bonding insulating layers surrounding the third and fourth metal pads, respectively.

11. The semiconductor package as claimed in claim 10, wherein the third and fourth bonding layers are on active surfaces of the second semiconductor chips in the first and second chip structures, respectively.

12. The semiconductor package as claimed in claim 10, wherein the third bonding layer is on inactive surfaces of the second semiconductor chips in the first chip structure, and the fourth bonding layer is on active surfaces of the second semiconductor chips in the second chip structure.

13. The semiconductor package as claimed in claim 1, wherein the first and second bonding layers are directly bonded and are in contact with each other.

14. The semiconductor package as claimed in claim 1, wherein:
the first and second metal pads include at least one of tungsten, aluminum, copper, tungsten nitride, tantalum nitride, and titanium nitride, and
the first and second bonding insulating layers include at least one of SiO, SiN, SiCN, SiOC, SiON and SiOCN.

15. A semiconductor package, comprising:
a first semiconductor chip including a first bonding layer on a surface, and having a device area in which semiconductor devices are disposed and a via area on at least one side of the device area, the via area being provided with through vias disposed therein; and
a chip structure stacked on the first semiconductor chip and bonded to the first semiconductor chip through the first bonding layer, and including a second bonding layer connected to the first bonding layer and a plurality of second semiconductor chips,
wherein the plurality of second semiconductor chips include a chip area and a scribe area outside of the chip area, respectively, the plurality of second semiconductor chips being connected to each other by the scribe area in the chip structure.

16. The semiconductor package as claimed in claim 15, wherein the through vias penetrate the first semiconductor chip and are electrically connected to the chip structure.

17. The semiconductor package as claimed in claim 15, wherein the device area and the via area have an upper surface and a lower surface that are coplanar in the first semiconductor chip.

18. A semiconductor package, comprising:
a first semiconductor chip including first metal pads on a surface;
a first redistribution portion on the first semiconductor chip and including a first redistribution layer electrically connected to the first semiconductor chip and second metal pads on a lower surface thereof and bonded to the first metal pads; and
a chip structure on the first redistribution portion and including a plurality of second semiconductor chips,
wherein the first semiconductor chip has a size that is substantially the same as a size of the chip structure on a plane.

19. The semiconductor package as claimed in claim 18, wherein:
the plurality of second semiconductor chips include a chip area and a scribe area outside of the chip area, respectively, the plurality of second semiconductor chips being connected to each other by the scribe area in the chip structure, and
the chip area and scribe area are on one substrate.

20. The semiconductor package as claimed in claim 18, further comprising a second redistribution portion disposed in a lower portion of the first semiconductor chip and including a second redistribution layer electrically connected to the first semiconductor chip.
